(19) United States
(12) Patent Application Publication
(10) Pub. No.: US 2023/0203073 A1
(43) Pub. Date: Jun. 29, 2023

(54) Organometallic Compound and Organic Light-Emitting Diode Including the Same

(71) Applicant: LG Display Co., Ltd., Seoul (KR)

(72) Inventors: Seongsu Jeon, Gwangmyeong-si (KR); Sangbeom Kim, Paju-si (KR); Kusun Choung, Seoul (KR)

(21) Appl. No.: 18/073,446

(22) Filed: Dec. 1, 2022

(30) Foreign Application Priority Data
Dec. 29, 2021 (KR) 10-2021-0191008

(51) Int. Cl. C07F 15/00

(52) U.S. Cl. CPC C07F 15/0033; H01L 51/50; H01L 51/0085

(57) ABSTRACT

Disclosed is a novel organometallic compound which reduces or suppresses triplet polaron quenching (TPQ) and roll-off phenomena to improve light-emitting efficiency and lifespan of an organic light-emitting diode including the compound. Further, the organic light-emitting diode including the compound is disclosed. The organic light-emitting diode including the compound may include a first electrode, a second electrode, and one or more light-emitting stacks between the first electrode and the second electrode.

### CROSS-REFERENCE TO RELATED APPLICATION

This application claims priority from Republic of Korea Patent Application No. 10-2021-0191008 filed on Dec. 29, 2021 in the Korean Intellectual Property Office, and all the benefits accruing therefrom under 35 U.S.C. 119, the contents of which in its entirety are herein incorporated by reference.

### BACKGROUND

### Field

The present disclosure relates to an organometallic compound and an organic light-emitting diode including the same. More specifically, the present disclosure relates to an organometallic compound which reduces or suppresses TPQ (Triplet Polaron Quenching) phenomenon and roll-off phenomenon to improve light-emitting efficiency and lifetime of an organic light-emitting diode including the same, and to an organic light-emitting diode including the same.

### Description of Related Art

As a display device is applied to various fields, interest with the display device is increasing. One of the display devices is an organic light-emitting display device including an organic light-emitting diode (OLED) which is rapidly developing. The organic light-emitting diode emits the light. Compared to conventional display devices, the organic light-emitting diode may operate at a low voltage, consume relatively little power, render excellent colors, and may be used in a variety of ways because a flexible substrate may be applied thereto. Further, a size of the organic light-emitting diode may be freely adjustable.

The organic light-emitting diode (OLED) has superior viewing angle and contrast ratio compared to a liquid crystal display (LCD), and is lightweight and is ultra-thin because the OLED does not require a backlight. The organic light-emitting diode includes a plurality of organic layers between a negative electrode (electron injection electrode; cathode) and a positive electrode (hole injection electrode; anode). The plurality of organic layers may include a hole injection layer, a hole transfer layer, a hole transfer auxiliary layer, an electron blocking layer, and a light-emitting layer, an electron transfer layer, etc.

In this organic light-emitting diode structure, when a voltage is applied across the two electrodes, electrons and holes are injected from the negative and positive electrodes, respectively, into the light-emitting layer and thus excitons are generated in the light-emitting layer and then fall to a ground state to emit light.

In the organic light-emitting diode, electric charges are injected into the light-emitting layer formed between the anode and the cathode, such that the electrons and holes are paired with each other and are recombined with each other to generate excitons, and energy of the excitons is converted into light.

In this regard, the excitons exist as singlet excitons and triplet excitons. In recent years, there is a trend to use phosphorescent materials rather than fluorescent materials for the light-emitting layer. When the fluorescent light-emitting material is used, singlets as about 25% of excitons generated in the light-emitting layer are used to emit light, while most of triplets as 75% of the excitons generated in the light-emitting layer are dissipated as heat. However, when the phosphorescent light-emitting material is used, singlets and triplets are used to emit light.

In the phosphorescent organic light-emitting diode, a phenomenon known as ‘triplet polaron quenching (TPQ)’ in which triplet excitons are quenched by polarons that are not converted to excitons at an interface between a hole transfer layer (HTL) and a light-emitting layer (EML) and inside the light-emitting layer (EML) may occur to impair performance of the organic light-emitting diode.

Specifically, when holes are transferred from the hole transfer layer (HTL) to the interface of the light-emitting layer (EML), holes may be transferred to a host of the light-emitting layer or may be transferred to a dopant thereof. In this regard, when holes from the hole transfer layer move to the dopant, the TPQ phenomenon increases. This acts as a factor to reduce efficiency of the organic light-emitting diode.

In addition, the polarons that are not converted to the exciton inside the light-emitting layer react with the dopant of the light-emitting layer to cause a quenching phenomenon. This TPQ phenomenon not only reduces the efficiency of the organic light-emitting diode but also intensifies the roll-off phenomenon that causes color-shift based on a current density, thereby impairing the performance of the organic light-emitting diode.

Therefore, in order to further improve the performance of the organic light-emitting diode using the phosphorescent light-emitting material, there is a need to develop a scheme that may reduce or suppress the TPQ phenomenon and the roll-off phenomenon occurring in the organic light-emitting diode.

### SUMMARY

A purpose of the present disclosure is to provide an organometallic compound with a novel structure that may be incorporated into a light-emitting layer of an organic light-emitting diode.

In addition, a purpose of the present disclosure is to provide a charge scavenger that causes quenching with polarons to reduce the triplet polaron quenching (TPQ) and roll-off phenomena occurring in the organic light-emitting diode, and to provide an organic light-emitting diode including the charge scavenger.

In addition, a purpose of the present disclosure is to provide an organometallic compound that acts as a charge scavenger to lower an operation voltage of the organic light-emitting diode and improve efficiency and lifetime of the organic light-emitting diode, and to provide an organic light-emitting diode including an organic light-emitting layer containing the organometallic compound.

Purposes of the present disclosure are not limited to the above-mentioned purpose. Other purposes and advantages of the present disclosure that are not mentioned may be understood based on following descriptions, and may be more clearly understood based on embodiments of the present disclosure. Further, it will be easily understood that the purposes and advantages of the present disclosure may be realized using means shown in the claims and combinations thereof.

In order to achieve the above purpose, one aspect of the present disclosure provides an organometallic compound having a novel structure represented by a following Chemical Formula 1: [Chemical Formula 1] Ir(L_{A})ₘ(L_{B})ₙ
wherein in the Chemical Formula 1, L_{A} may be a main ligand represented by one selected from a group consisting of following Chemical Formula 2-1 to Chemical Formula 2-3, and L_{B} may be an ancillary ligand represented by a following Chemical Formula 3:

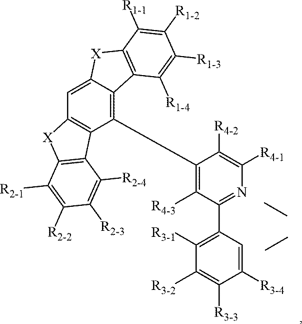

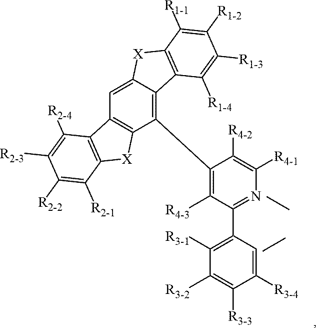

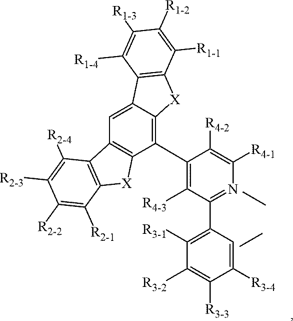

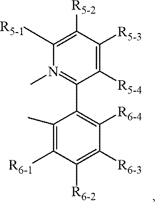

wherein in each of the Chemical Formulas 2-1 to 2-3,
X may represent one selected from a group consisting of O, S, NR₇ and C(R₈)(R₉),
each of R₁₋₁, R₁₋₂, R₁₋₃, R₁₋₄, R₂₋₁, R₂₋₂, R₂₋₃, R₂₋₄, R₃₋₁, R₃₋₂, R₃₋₃, R₃₋₄, R₄₋₁, R₄₋₂ and R₄₋₃ may independently represent one selected from a group consisting of hydrogen, deuterium, halide, C1-C30 alkyl, C3-C30 cycloalkyl, C1-C30 heteroalkyl, C1-C30 arylalkyl, C1-C30 alkoxy, C1-C30 aryloxy, amino, silyl, C2-C30 alkenyl, C3-C30 cycloalkenyl, C3-C30 heteroalkenyl, C2-C30 alkynyl, C6-C40 aryl, C3-C40 heteroaryl, acyl, carbonyl, carboxylic acid, ester, nitrile, isonitrile, sulfanyl, sulfinyl, sulfonyl, phosphino, and combinations thereof,
two adjacent substituents among R₁₋₃, R₁₋₂, R₁₋₃, R₁₋₄, R₂₋₁, R₂₋₂, R₂₋₃, R₂₋₄, R₃₋₁, R₃₋₂, R₃₋₃, R₃₋₄, R₄₋₁, R₄₋₂ and R₄₋₃ may be connected to each other to form one ring structure selected from a group consisting of a substituted or unsubstituted C3-C20 cycloalkyl group, a substituted or unsubstituted C2-C20 heterocycloalkyl group, a substituted or unsubstituted C7-C20 arylalkyl group, a substituted or unsubstituted C2-C20 heteroarylalkyl group, a substituted or unsubstituted C3-C20 cycloalkenyl group, a substituted or unsubstituted C6-C30 aryl group, and a substituted or unsubstituted C3-C30 heteroaryl group,
each of R₇, R₈, and R₉ may independently represent one selected from a group consisting of C1-C30 alkyl, C3-C30 cycloalkyl, C1-C30 heteroalkyl, C1-C30 arylalkyl, C1-C30 alkoxy, C1-C30 aryloxy, amino, silyl, C2-C30 alkenyl, C3-C30 cycloalkenyl, C3-C30 heteroalkenyl, C2-C30 alkynyl, C6-C40 aryl, and C3-C40 heteroaryl,
wherein in the Chemical Formula 3,
each of R₅₋₁, R₅₋₂, R₅₋₃, R₅₋₄, R₆₋₁, R₆₋₂, R₆₋₃ and R₆₋₄ may independently represent one selected from a group consisting of hydrogen, deuterium, a C1-C5 straight-chain alkyl group, and a C1-C5 branched alkyl group, wherein the C1-C5 straight-chain alkyl group or C1-C5 branched alkyl group may be substituted with at least one selected from deuterium and halogen,
two adjacent substituents among R₅₋₁, R₅₋₂, R₅₋₃, R₅₋₄, R₆₋₁, R₆₋₂, R₆₋₃ and R₆₋₄ may be connected to each other to form one ring structure selected from a group consisting of a substituted or unsubstituted C3-C20 cycloalkyl group, a substituted or unsubstituted C2-C20 heterocycloalkyl group, a substituted or unsubstituted C7-C20 arylalkyl group, a substituted or unsubstituted C2-C20 heteroarylalkyl group, a substituted or unsubstituted C3-C20 cycloalkenyl group, a substituted or unsubstituted C6-C30 aryl group, and a substituted or unsubstituted C3-C30 heteroaryl group,
m may be 1, 2 or 3, n may be 0, 1 or 2, and a sum of m and n may be 3.

Another aspect of the present disclosure provides an organic light-emitting device comprising: a first electrode; a second electrode facing the first electrode; and a light-emitting stack disposed between the first electrode and the second electrode, wherein the light-emitting stack includes an organic layer, wherein the organic layer includes a hole transfer layer and a red light-emitting layer, wherein the hole transfer layer includes a hole transfer material, wherein the red light-emitting layer contains a red host, a red dopant, and a charge scavenger, wherein the charge scavenger includes the organometallic compound having a novel structure represented by the above Chemical Formula 1.

The organometallic compound according to the present disclosure may be contained in the light-emitting layer of the organic light-emitting diode, such that the triplet polaron quenching (TPQ) phenomenon and the roll-off phenomenon occurring in the organic light-emitting diode may be reduced or suppressed. Thus, the operation voltage of the organic light-emitting diode may be lowered, and the efficiency and lifespan characteristics of the organic light-emitting diode may be improved.

Effects of the present disclosure are not limited to the above-mentioned effects, and other effects as not mentioned will be clearly understood by those skilled in the art from following descriptions.

### BRIEF DESCRIPTION OF DRAWINGS

FIG. 1 is a cross-sectional view schematically showing an organic light-emitting diode in which a light-emitting layer contains an organometallic compound according to an illustrative embodiment of the present disclosure.

FIG. 2 is a cross-sectional view schematically illustrating an organic light-emitting diode having a tandem structure having two light-emitting stacks and containing an organometallic compound represented by the Chemical Formula 1 according to an illustrative embodiment of the present disclosure.

FIG. 3 is a cross-sectional view schematically illustrating an organic light-emitting diode having a tandem structure having three light-emitting stacks and containing an organometallic compound represented by the Chemical Formula 1 according to an illustrative embodiment of the present disclosure.

FIG. 4 is a cross-sectional view schematically illustrating an organic light-emitting display device including an organic light-emitting diode according to an illustrative embodiment of the present disclosure.

### DETAILED DESCRIPTION

Advantages and features of the present disclosure, and a method of achieving the advantages and features will become apparent with reference to embodiments described later in detail together with the accompanying drawings. However, the present disclosure is not limited to the embodiments as disclosed below, but may be implemented in various different forms. Thus, these embodiments are set forth only to make the present disclosure complete, and to completely inform the scope of the present disclosure to those of ordinary skill in the technical field to which the present disclosure belongs, and the present disclosure is only defined by the scope of the claims.

A shape, a size, a ratio, an angle, a number, etc. disclosed in the drawings for describing the embodiments of the present disclosure are illustrative, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “including”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof.

It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

The features of the various embodiments of the present disclosure may be partially or entirely combined with each other, and may be technically associated with each other or operate with each other. The embodiments may be implemented independently of each other and may be implemented together in an association relationship.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, a phrase ‘adjacent substituents are connected to each other to form a ring (or a ring structure)’ means that adjacent substituents may bind to each other to form a substituted or unsubstituted alicyclic or aromatic ring. A phrase ‘adjacent substituent’ to a certain substituent may mean a substituent replacing an atom directly connected to an atom which the certain substituent replaces, a substituent that is sterically closest to the certain substituent, or a substituent replacing an atom replaced with the certain substituent. For example, two substituents replacing an ortho position in a benzene ring structure and two substituents replacing the same carbon in an aliphatic ring may be interpreted as ‘adjacent substituents’.

In the present disclosure, a HOMO (Highest Occupied Molecular Orbital) energy level is based on cyclic voltammetry (CV) and is calculated based on a following condition and an equation.

HOMO Energy Level (CV)

| Solution concentration | Standard electrode | Electrolyte | | | Standard material | Energy level equation |
|---|---|---|---|---|---|---|
| | | Solute | Solvent | Concentration | | |
| 1 mM | Ag/AgCl | Bu₄NPF₆ | DMF | 0.1 M | ferrocene | E=-4.8-(Eₒₓ-E_{fc})(eV) |
| | | | | | | Eₒₓ: oxidation on-set value |
| | | | | | | E_{fc}: ferrocene energy |

In the present disclosure, a triplet energy (T₁) is obtained as follows: photoluminescence of a solution in which a material to be measured is dissolved in 2-methyl THF solvent is measured in an environment of 77 K to obtain a PL spectrum, and an energy level (unit: eV) of a first peak of the obtained PL spectrum is converted to the triplet energy.

Hereinafter, a structure of the organometallic compound according to the present disclosure and an organic light-emitting diode including the same will be described.

An organometallic compound according to an embodiment of the present disclosure is a novel iridium complex compound represented by a following Chemical Formula 1, wherein a main ligand and an ancillary ligand linked to iridium (Ir) as a central coordination metal may be represented by L_{A} and L_{B} of the following Chemical Formula 1, respectively. In each of the main ligand and the ancillary ligand, a dotted line at 2-phenylpyridine moiety indicates binding to the central metal Ir (iridium):

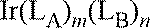

Specifically, L_{A} as the main ligand has a basic structure in which a polycyclic fused ring (hexagonal-pentagonal-hexagonal-pentagonal-hexagonal) is connected to pyridine of 2-phenylpyridine. L_{A} as the main ligand may be classified into following Chemical Formula 2-1 to Chemical Formula 2-3 based on an orientation of two Xs of the polycyclic fused ring:

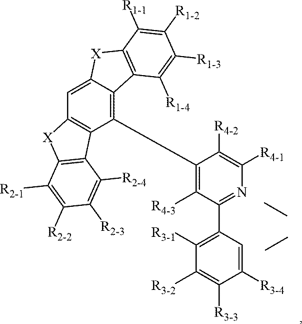

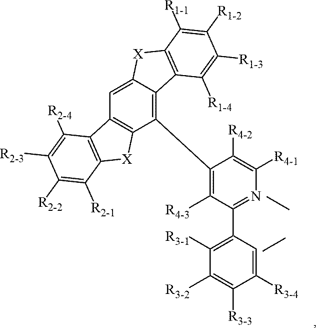

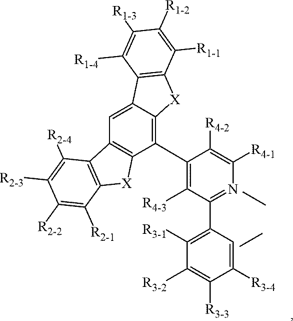

wherein in each of the Chemical Formulas 2–1 to 2–3,
X may represent one selected from a group consisting of O, S, NR₇ and C(R₈)(R₉),
each of R₁₋₁, R₁₋₂, R₁₋₃, R₁₋₄, R₂₋₁, R₂₋₂, R₂₋₃, R₂₋₄, R₃₋₁, R₃₋₂, R₃₋₃, R₃₋₄, R₄₋₁, R₄₋₂ and R₄₋₃ may independently represent one selected from a group consisting of hydrogen, deuterium, halide, C1-C30 alkyl, C3-C30 cycloalkyl, C1-C30 heteroalkyl, C1-C30 arylalkyl, C1-C30 alkoxy, C1-C30 aryloxy, amino, silyl, C2-C30 alkenyl, C3-C30 cycloalkenyl, C3-C30 heteroalkenyl, C2-C30 alkynyl, C6-C40 aryl, C3-C40 heteroaryl, acyl, carbonyl, carboxylic acid, ester, nitrile, isonitrile, sulfanyl, sulfinyl, sulfonyl, phosphino, and combinations thereof,
two adjacent substituents among R₁₋₃, R₁₋₂, R₁₋₃, R₁₋₄, R₂₋₁, R₂₋₂, R₂₋₃, R₂₋₄, R₃₋₁, R₃₋₂, R₃₋₃, R₃₋₄, R₄₋₁, R₄₋₂ and R₄₋₃ may be connected to each other to form one ring structure selected from a group consisting of a substituted or unsubstituted C3-C20 cycloalkyl group, a substituted or unsubstituted C2-C20 heterocycloalkyl group, a substituted or unsubstituted C7-C20 arylalkyl group, a substituted or unsubstituted C2-C20 heteroarylalkyl group, a substituted or unsubstituted C3-C20 cycloalkenyl group, a substituted or unsubstituted C6-C30 aryl group, and a substituted or unsubstituted C3-C30 heteroaryl group,
each of R₇, R₈, and R₉ may independently represent one selected from a group consisting of C1-C30 alkyl, C3-C30 cycloalkyl, C1-C30 heteroalkyl, C1-C30 arylalkyl, C1-C30 alkoxy, C1-C30 aryloxy, amino, silyl, C2-C30 alkenyl, C3-C30 cycloalkenyl, C3-C30 heteroalkenyl, C2-C30 alkynyl, C6-C40 aryl, and C3-C40 heteroaryl.

In addition, L_{B} as the ancillary ligand may be a bidentate ligand, and may be represented by a following Chemical Formula 3:

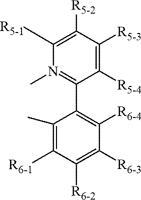

wherein in the Chemical Formula 3,
each of R₅₋₁, R₅₋₂, R₅₋₃, R₅₋₄, R₆₋₁, R₆₋₂, R₆₋₃ and R₆₋₄ may independently represent one selected from a group consisting of hydrogen, deuterium, a C1-C5 straight-chain alkyl group, and a C1-C5 branched alkyl group, wherein the C1-C5 straight-chain alkyl group or C1-C5 branched alkyl group may be substituted with at least one selected from deuterium and halogen,
two adjacent substituents among R₅₋₁, R₅₋₂, R₅₋₃, R₅₋₄, R₆₋₁, R₆₋₂, R₆₋₃ and R₆₋₄ may be connected to each other to form one ring structure selected from a group consisting of a substituted or unsubstituted C3-C20 cycloalkyl group, a substituted or unsubstituted C2-C20 heterocycloalkyl group, a substituted or unsubstituted C7-C20 arylalkyl group, a substituted or unsubstituted C2-C20 heteroarylalkyl group, a substituted or unsubstituted C3-C20 cycloalkenyl group, a substituted or unsubstituted C6-C30 aryl group, and a substituted or unsubstituted C3-C30 heteroaryl group.

In the Chemical Formula 1, m may be 1, 2 or 3, n may be 0, 1 or 2, and a sum of m and n may be 3.

The organometallic compound according to an implementation of the present disclosure may have a heteroleptic or homoleptic structure. For example, the organometallic compound according to an embodiment of the present disclosure may have a heteroleptic structure in which in the Chemical Formula I, m is 1 and n is 2; or a heteroleptic structure where m is 2 and n is 1; or a homoreptic structure where m is 3 and n is 0.

A specific example of the compound represented by the Chemical Formula 1 of the present disclosure may include one selected from a group consisting of following compounds 1 to 20. However, the specific example of the compound represented by the Chemical Formula 1 of the present disclosure is not limited thereto as long as it meets the above definition of the Chemical Formula 1:

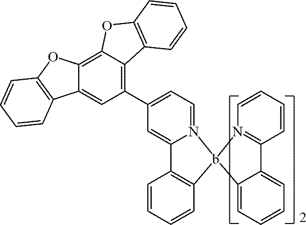

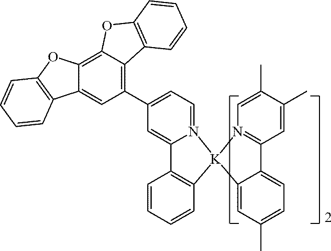

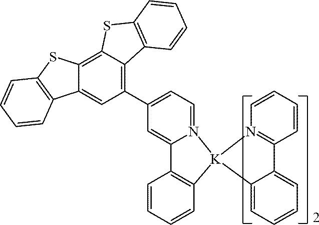

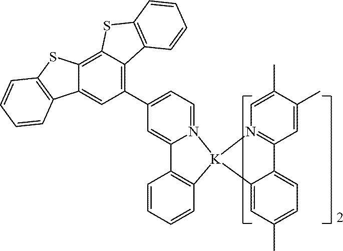

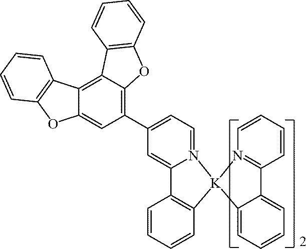

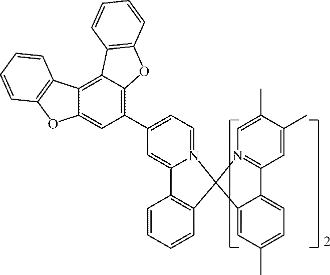

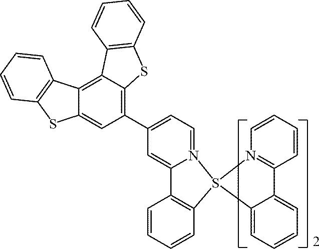

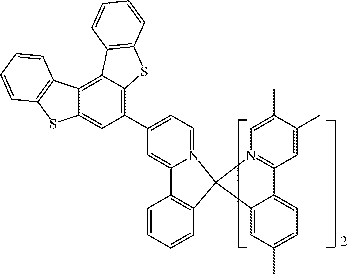

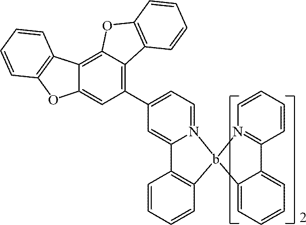

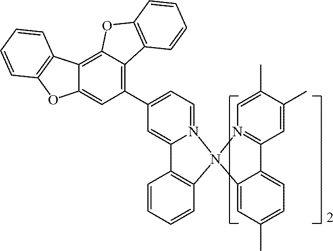

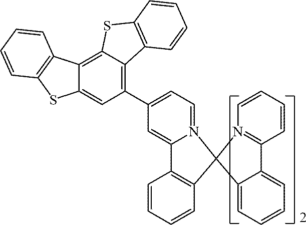

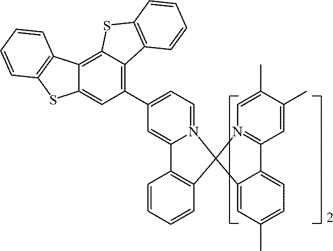

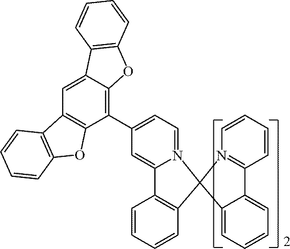

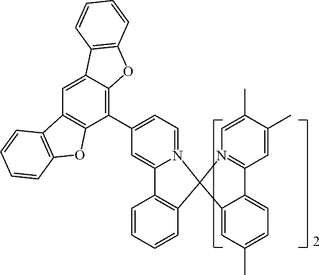

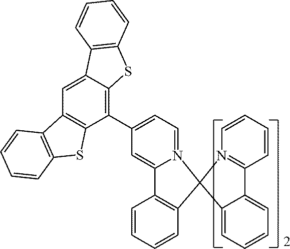

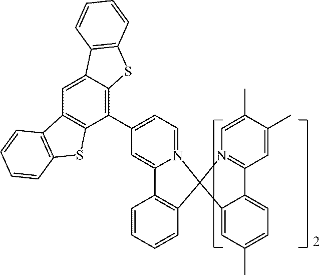

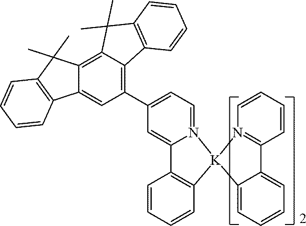

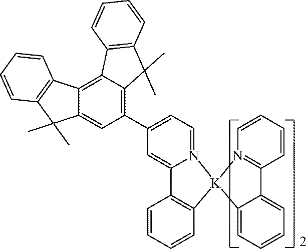

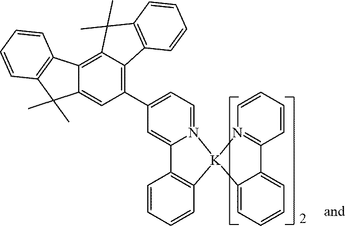

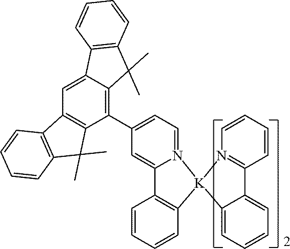

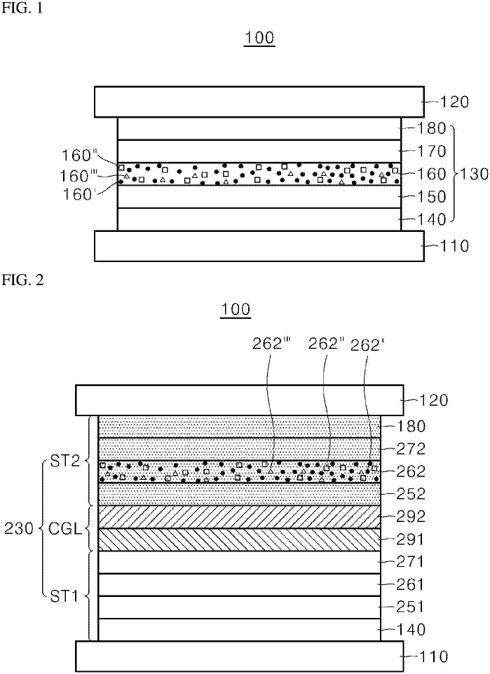

Referring to FIG. 1, an organic light-emitting device 100 according to an embodiment of the present disclosure may include a first electrode 110, a second electrode 120 facing the first electrode 110, and a light-emitting stack disposed between the first electrode 110 and the second electrode 120, wherein the light-emitting stack include an organic layer 130. The organic layer 130 may include a hole transfer layer (HTL) 150 and a red light-emitting layer 160, wherein the hole transfer layer 150 may include a hole transfer material, and the red light-emitting layer 160 may include a red host 160′ and a red dopant 160″ doped therein.

In particular, in the present disclosure, the red light-emitting layer 160 may contain not only the red host 160′ and the red dopant 160″ but also the charge scavenger 160‴. Thus, as described above, the triplet polaron quenching (TPQ) and the roll-off occurring at the interface between the hole transfer layer and the light-emitting layer and/or inside the light-emitting layer (EML) may be reduced or suppressed. Thus, the present disclosure has been completed.

Specifically, in the prior art, it is common that the light-emitting layer contains a host material and a dopant material doped therein. However, according to the present disclosure, a material causing quenching with polaron is additionally doped into the light-emitting layer, thereby reducing or suppressing the roll-off phenomenon and the TPQ phenomenon of the dopant material. In this regard, the material causing quenching with polarons to reduce or suppress the roll-off phenomenon and the TPQ phenomenon of the dopant material is referred to as the charge scavenger 160‴.

That is, when the host 160′ of the light-emitting layer 160 is doped with the dopant 160″ and the charge scavenger 160‴, following effects may be achieved.

i) holes injected from the hole transfer layer 150 into the dopant 160″ of the light-emitting layer 160 may be trapped by the charge scavenger 160‴, thereby reducing accumulation of holes at the interface between the hole transfer layer 150 and the light-emitting layer 160, such that the TPQ phenomenon of the dopant 160″ occurring at the interface may be reduced, thereby improving the efficiency and lifespan of the organic light-emitting diode.

ii) the charge scavenger 160‴ may cause quenching phenomenon with the polaron inside the light-emitting layer 160, thereby reducing the TPQ phenomenon of the dopant 160″ occurring inside the light-emitting layer 160. In an organic light-emitting diode including a tandem structure as described below, the charge scavenger 160‴ may control color-shift according to current density, such that the efficiency and lifespan of the organic light-emitting diode may be improved, and the roll-off phenomenon may also be reduced.

In order that the charge scavenger exhibits the effects as described above, it is preferable that the red dopant, the charge scavenger, and the hole transfer layer material of the organic light-emitting diode according to the present disclosure satisfy a following condition (1).

$$\left|{\text{HOMO}}_{\left(\text{RD}\right)}\right| \leq \left|{\text{HOMO}}_{\left(\text{CS}\right)}\right| \leq \left|{\text{HOMO}}_{\left(\text{HTL}\right)}\right|$$

In the condition (1), | HOMO_{(RD)} | denotes an absolute value of a HOMO energy level of the red dopant, and | HOMO_{(CS)} | denotes an absolute value of a HOMO energy level of the charge scavenger, and | HOMO_{(HTL)} | denotes an absolute value of a HOMO energy level of the hole transfer material.

When the absolute value of the HOMO energy level of the charge scavenger 160‴ satisfies the condition (1), holes injected from the hole transfer layer 150 to the dopant 160″ of the light-emitting layer 160 are trapped by the charge scavenger 160‴, thereby reducing the TPQ phenomenon.

According to the present disclosure, it is preferable that the red dopant and the charge scavenger of the organic light-emitting diode further satisfy a following condition (2).

$${\text{T}}_{1 \left(\text{RD}\right)} < {\text{T}}_{1 \left(\text{CS}\right)}$$

In the condition (2), T₁_{(RD)} denotes a triplet energy level of the red dopant, and T₁ (cs) denotes a triplet energy level of the charge scavenger.

The charge scavenger 160‴ is doped into the host 160′ of the light-emitting layer 160, and participates in light emission together with the red dopant 160″ and thus shifts color coordinates of the light-emitting layer to reduce target color rendering accuracy. Further, in this case, it is difficult to reduce or suppress the TPQ phenomenon. For this reason, it is desirable to satisfy the condition (2) such that the triplet energy level value of the charge scavenger 160‴ is higher than the triplet energy level value of the red dopant 160″, and thus, energy transfer from the charge scavenger 160‴ to the red dopant 160″ may occur.

Further, in order to achieve the red light-emitting layer 160 while satisfying the condition (2), it is preferable that T₁_{(RD)} may be in a range of 1.8 to 2.2 eV, and T₁_{(CS)} may be lower than or equal to 2.6 eV. More preferably, T₁_{(RD)} may be in a range of 1.8 to 2.0 eV, and T₁_{(CS)} may be lower than or equal to 2.4 eV. Most preferably, T₁_{(RD)} may be in a range of 1.9 to 2.0 eV, and T₁_{(CS)} may be lower than or equal to 2.3 eV.

According to the present disclosure, to improve the light-emitting efficiency of the diode, the red light-emitting layer 160 may be formed by doping the red dopant 160″ and the charge scavenger 160‴ into the red host 160′.

Preferably, a doping concentration of each of the red dopant 160″ and the charge scavenger 160‴ may be in a range of 1 to 30% by weight, based on a total weight of the red host 160′. For example, the doping concentration of each of the red dopant 160″ and the charge scavenger 160‴ may be in a range of 3 to 20% by weight, such as 5 to 15% by weight, such as 5 to 10% by weight, such as 3 to 8% by weight, such as 3 to 5% by weight, based on the total weight of the red host 160′. The present disclosure is not limited thereto, and the doping concentration of each of the red dopant and the charge scavenger may be adjusted based on a type of a material as used.

Further, in the present disclosure, it was experimentally identified based on a result of intensive research that the doping concentration of the charge scavenger 160″ may be smaller than two times of the doping concentration of the red dopant 160″.

As described above, the charge scavenger may be doped into the light-emitting layer and may act as a light-emitting dopant. Therefore, when the doping concentration of the charge scavenger is greater than or equal to two times of the doping concentration of the red dopant, a desired red light-emitting layer cannot be realized while the red dopant is doped therein, but, rather, a chromaticity coordinate system (CIEx, CIEy) may shift such that a color of emitted light is greenish.

Specifically, a chromaticity coordinate system of the red light-emitting layer as obtained while increasing the doping concentration of the charge scavenger was compared with the chromaticity coordinate system (CIEx, CIEy) of the red light-emitting layer in which the charge scavenger is not doped. Thus, as a difference from the reference chromaticity coordinate system is larger, it is difficult to render a target color of emitted light. For example, when an absolute value of a change amount of CIEx or CIEy exceeds 0.004 to 0.005, color of light emitted from an actually manufactured diode tends to be greenish. Especially, CIEx may act as a more important factor in color rendering in the red light-emitting layer.

Thus, the charge scavenger 160‴ may be doped into the host such that the TPQ and roll-off phenomena may be suppressed or reduced to improve the efficiency of the organic light-emitting diode. In particular, when considering color rendering, it is preferable to adjust the doping concentration of the charge scavenger 160‴ to be smaller than two times of the doping concentration of the red dopant 160″.

The organic light-emitting diode according to the present disclosure includes the features of the present disclosure as described above. The organic layer 130 disposed between the first electrode 110 and the second electrode 120 of the organic light-emitting diode 100 of FIG. 1 may be embodied as a stack formed by sequentially stacking a hole injection layer (HIL) 140, the hole transfer layer (HTL) 150, a light-emitting layer (EML) 160, an electron transfer layer (ETL) 170 and an electron injection layer (EIL) 180 on the first electrode 110. The second electrode 120 may be formed on the electron injection layer 180, and a protective layer (not shown) may be formed thereon.

A thickness of each of the first electrode 110, the second electrode 120 and each of the layers included in the organic layer 130 according to the present disclosure is not particularly limited and may be adjusted as necessary. For example, a thickness of each of the first electrode 110 and the second electrode 120 may be in a range of 50 to 200 nm, a thickness of the hole injection layer 140 may be in a range of 5 to 10 nm, a thickness of the hole transfer layer 150 may be in a range of 5 to 130 nm, a thickness of the light-emitting layer 160 may be in a range of 5 to 50 nm, a thickness of the electron transfer layer 170 may be in a range of 5 to 50 nm, and a thickness of the electron injection layer 180 may be in a range of 5 to 50 nm.

Further, although not shown in FIG. 1, a hole transfer auxiliary layer may be further added between the hole transfer layer 150 and the red light-emitting layer 160. The hole transfer auxiliary layer may contain a compound having good hole transfer properties, and may reduce a difference between HOMO energy levels of the hole transfer layer 150 and the light-emitting layer 160 so as to adjust the hole injection properties. Thus, accumulation of holes at an interface between the hole transfer auxiliary layer and the light-emitting layer 160 may be reduced. Accordingly, deterioration of the diode may be reduced, and thus the diode may be stabilized, thereby improving efficiency and lifespan thereof.

The first electrode 110 may act as a positive electrode, and may be made of ITO, IZO, tin-oxide, or zinc-oxide as a conductive material having a relatively large work function value. However, the present disclosure is not limited thereto.

The second electrode 120 may act as a negative electrode, and may include aluminum (Al), magnesium (Mg), calcium (Ca), or silver (Ag) as a conductive material having a relatively small work function value, or an alloy or combination thereof. However, the present disclosure is not limited thereto.

The hole injection layer 140 may be positioned between the first electrode 110 and the hole transfer layer 150. The hole injection layer 140 may have a function of improving interface characteristics between the first electrode 110 and the hole transfer layer 150, and may be selected from a material having appropriate conductivity. The hole injection layer 140 may include a compound selected from a group consisting of a secondary amine-based compound, a tertiary amine-based compound, a radialene-based compound, an indacene-based compound, a metal cyanine-based compound, and combinations thereof. Specific examples thereof may include at least one selected from a group consisting of HATCN, MTDATA, TCTA, CuPc, TDAPB, PEDOT/PSS, N1,N1′-([1,1′-biphenyl]-4,4′-diyl)bis(N1,N4,N4-triphenylbenzene-1,4-diamine), and the like. Preferably, the hole injection layer 140 may include HATCN. However, the present disclosure is limited thereto.

The hole transfer layer 150 may be positioned adjacent to the light-emitting layer and between the first electrode 110 and the light-emitting layer 160. A material of the hole transfer layer 150 may include a compound selected from a group consisting of TAPC, TPD, NPB, CBP, N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl)-4-amine, and the like. Preferably, the material of the hole transfer layer 150 may include TAPC or NPB. However, the present disclosure is not limited thereto.

The red light-emitting layer 160 according to the present disclosure may be embodied as a phosphorescent red light-emitting layer, and may contain the red host 160′, and the red dopant 160″ and the charge scavenger 160‴ doped into the red host 160′.

For example, any material used for the red host 160′ in the present technical field may be used as long as it can achieve the effect of the present disclosure. For example, the red host 160′ according to the present disclosure may include one selected from a compound containing a carbazole group, a tertiary amine-based compound, a compound containing a pyridine group, a compound containing a pyrimidine group, and a compound containing a triazine group. More specifically, the red host 160′ according to the present disclosure may include one selected from DMAC-BPP, PXZ-TRZ, DPTPCz, CBP, mCP(1,3-bis(carbazol-9-yl), and the like. However, the present disclosure is not limited thereto. For example, any material used for the red host 160′ in the present technical field may be used as long as it can achieve the effect of the present disclosure.

Further, for example, the red dopant 160″ in accordance with the present disclosure may preferably include a metal complex of iridium (Ir) or platinum (Pt) having a large atomic number. The iridium (Ir) metal complex is preferable. More specifically, the red dopant 160″ may include a red dopant material selected from Ir(piq)₃, Ir(piq)₂(acac), Ir(2-phq)₃, Ir(ppy)₃, Ir(ppy)₂(bpmp), Ir(ppz)₃, Ir(piq)₃, Ir(ppy)₂(bpmp), and the like. However, the present disclosure is not limited thereto. For example, the HOMO energy level of the red dopant 160″ is preferably in a range of -5.5 to -4.8 (eV), and T₁ thereof is preferably in a range of 1.8 to 2.2 (eV). The HOMO energy level of the red dopant 160″ and T₁ thereof are not necessarily limited thereto as long as those are applicable to the red light-emitting layer.

According to the present disclosure, when the material of the hole transfer layer of the organic light-emitting diode, and the material of the red dopant of the red light-emitting layer thereof are selected, a material of the charge scavenger 160‴ may be selected as a material having a HOMO energy level satisfying at least the above-mentioned condition (1). Furthermore, it is more preferable to select a material having the HOMO and the triplet energy level satisfying both the conditions (1) and (2) as the material of the charge scavenger 160‴. Thus, a material satisfying the condition (1) or both the conditions (1) and (2) may be selected as a material of the charge scavenger 160‴.

According to a preferred aspect of the present disclosure, the charge scavenger may include, but is not limited to, an organometallic compound represented by the following Chemical Formula 1 of the present disclosure:

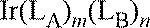

wherein in the Chemical Formula 1, L_{A} may be a main ligand represented by one selected from a group consisting of following Chemical Formula 2-1 to Chemical Formula 2-3, and L_{B} may be an ancillary ligand represented by a following Chemical Formula 3:

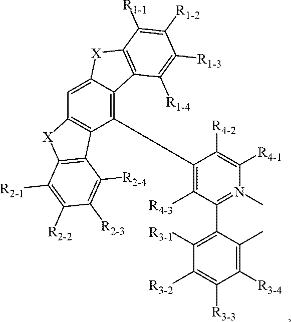

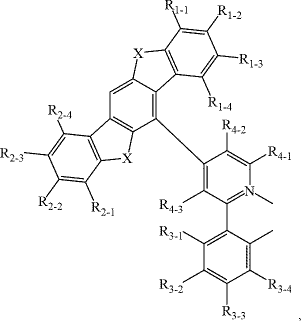

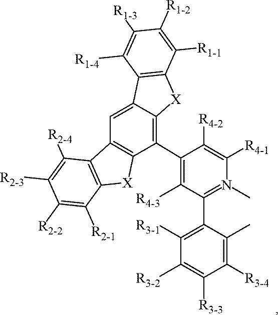

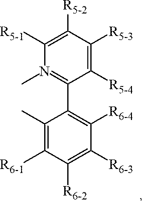

Definitions of each of the Chemical Formulas 1, 2-1, 2-2, 2-3 and 3 are the same as those as described in the Claims, and the above descriptions of the present disclosure.

Further, the electron transfer layer 170 and the electron injection layer 180 may be sequentially stacked between the red light-emitting layer 160 and the second electrode 120. A material of the electron transfer layer 170 requires high electron mobility such that electrons may be stably supplied to the light-emitting layer under smooth electron transfer.

For example, the material of the electron transfer layer 170 may include a compound selected from a group consisting of Alq3 (tris(8-hydroxyquinolino)aluminum), Liq (8-hydroxyquinolinolatolithium), PBD (2-(4-biphenylyl)-5-(4-tert-butylphenyl)-1,3,4oxadiazole), TAZ (3-(4-biphenyl)4-phenyl-5-tert-butylphenyl-1,2,4-triazole), spiro-PBD, BAlq (bis(2-methyl-8-quinolinolate)-4-(phenylphenolato)aluminium), SAlq, TPBi (2,2′,2-(1,3,5-benzinetriyl)-tris(1-phenyl-1-H-benzimidazole), oxadiazole, triazole, phenanthroline, benzoxazole, benzthiazole, ZADN (2-(4-(9,10-di(naphthalen-2-yl)anthracen-2-yl)phenyl)-1-phenyl-1H-benzo[d]imidazole), and the like. Preferably, the material of the electron transfer layer 170 may include ZADN. However, the present disclosure is not limited thereto.

The electron injection layer 180 serves to facilitate electron injection. A material of the electron injection layer may include a compound selected from a group consisting of Alq3 (tris(8-hydroxyquinolino)aluminum), PBD, TAZ, spiro-PBD, BAlq, SAlq, Bphen, and the like. However, the present disclosure is not limited thereto. Alternatively, the electron injection layer 180 may include a mixture of the organic compound (or organometallic compound) and a metal material, or may include a metal material alone. For example, the electron injection layer 180 may include a mixture of Bphen and LiF.

In this regard, the metal material may include, for example, one or more selected from a group consisting of Liq, LiF, NaF, KF, RbF, CsF, FrF, BeF₂, MgF₂, CaF₂, SrF₂, BaF₂, RaF₂, and the like. However, the present disclosure is not limited thereto. Further, a material of the electron injection layer 180 may include a mixture of the metal material and a metal element having a low work function, such as ytterbium (Yb), calcium (Ca), strontium (Sr), barium (Ba), lanthanum (La), etc. For example, a mixture of LiF and ytterbium (Yb) may be used as a material of the electron injection layer 180.

The organic light-emitting diode according to the present disclosure may be embodied as a white light-emitting diode having a tandem structure. The tandem organic light-emitting diode according to an illustrative embodiment of the present disclosure may be formed in a structure in which adjacent ones of two or more light-emitting stacks are connected to each other via a charge generation layer (CGL). The organic light-emitting diode may include at least two light-emitting stacks disposed on a substrate, wherein each of the at least two light-emitting stacks includes first and second electrodes facing each other, and the light-emitting layer disposed between the first and second electrodes to emit light in a specific wavelength band. The plurality of light-emitting stacks may emit light of the same color or different colors. In addition, one or more light-emitting layers may be included in one light-emitting stack, and the plurality of light-emitting layers may emit light of the same color or different colors.

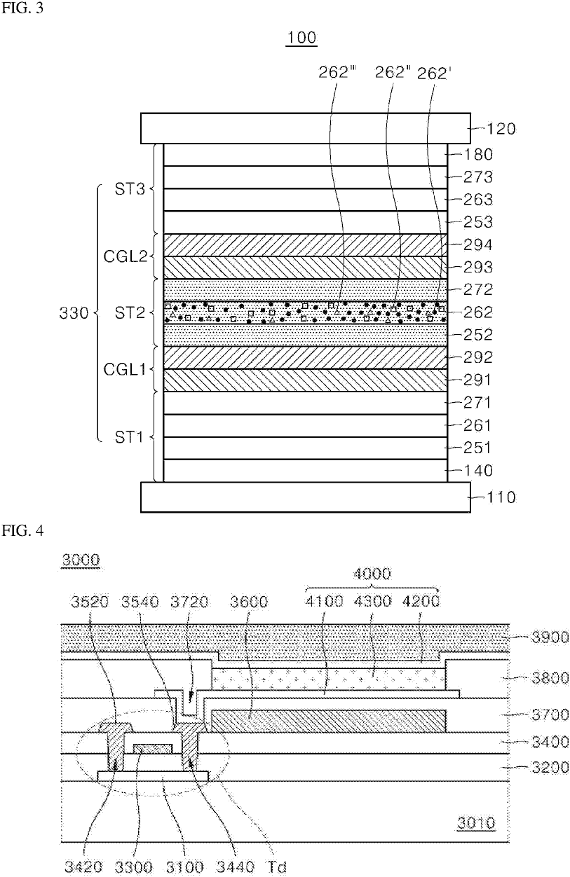

FIG. 2 and FIG. 3 are cross-sectional views schematically showing an organic light-emitting diode in a tandem structure having two light-emitting stacks and an organic light-emitting diode in a tandem structure having three light-emitting stacks, respectively, according to some implementations of the present disclosure.

As shown in FIG. 2, an organic light-emitting diode 100 according to the present disclosure include a first electrode 110 and a second electrode 120 facing each other, and an organic layer 230 positioned between the first electrode 110 and the second electrode 120. The organic layer 230 may be positioned between the first electrode 110 and the second electrode 120 and may include a first light-emitting stack ST1 including a first light-emitting layer 261, a second light-emitting stack ST2 positioned between the first light-emitting stack ST1 and the second electrode 120 and including a second light-emitting layer 262, and the charge generation layer CGL positioned between the first and second light-emitting stacks ST1 and ST2. The charge generation layer CGL may include an N-type charge generation layer 291 and a P-type charge generation layer 292. At least one of the first light-emitting layer 261 and the second light-emitting layer 262 may be a red light-emitting layer according to the present disclosure. The first light-emitting stack ST1 may further include a first HTL 251 and a first ETL 271. The second light-emitting stack ST2 may further include a second HTL 252 and a second ETL 272. In one embodiment, the first HTL 251 and the second HTL 252 may have similar or identical structure and materials as the HTL 150 of FIG. 1. In one embodiment, the first ETL 271 and the second ETL 272 may have similar or identical structure and materials as the ETL 170 of FIG. 1.

For example, as shown in FIG. 2, the second light-emitting layer 262 of the second light-emitting stack ST2 may contain a host material 262′, and a red dopant 262″ and a charge scavenger 262‴, wherein the charge scavenger 262‴ may include the organometallic compound represented by the Chemical Formula 1 of the present disclosure.

Although not shown in FIG. 2, each of the first and second light-emitting stacks ST1 and ST2 may further include, in addition to each of the first light-emitting layer 261 and the second light-emitting layer 262, an additional light-emitting layer.

As shown in FIG. 3, the organic light-emitting diode 100 according to the present disclosure include the first electrode 110 and the second electrode 120 facing each other, and an organic layer 330 positioned between the first electrode 110 and the second electrode 120. The organic layer 330 may be positioned between the first electrode 110 and the second electrode 120 and may include the first light-emitting stack ST1 including the first light-emitting layer 261, the second light-emitting stack ST2 including the second light-emitting layer 262, a third light-emitting stack ST3 including a third light-emitting layer 263, a first charge generation layer CGL1 positioned between the first and second light-emitting stacks ST1 and ST2, and a second charge generation layer CGL2 positioned between the second and third light-emitting stacks ST2 and ST3. The first charge generation layer CGL1 may include a N-type charge generation layers 291 and a P-type charge generation layer 292. The second charge generation layer CGL2 may include a N-type charge generation layers 293 and a P-type charge generation layer 294. At least one of the first light-emitting layer 261, the second light-emitting layer 262, and the third light-emitting layer 263 may be a red light-emitting layer according to the present disclosure. For example, as shown in FIG. 3, the second light-emitting layer 262 of the second light-emitting stack ST2 may contain a host material 262′, and a red dopant 262″ and a charge scavenger 262‴, wherein the charge scavenger 262‴ may include the organometallic compound represented by the Chemical Formula 1 of the present disclosure. The first light-emitting stack ST1 may further include a first HTL 251 and a first ETL 271. The second light-emitting stack ST2 may further include a second HTL 252 and a second ETL 272. The third light-emitting stack ST3 may further include a third HTL 253 and third ETL 273. In one embodiment, the first HTL 251, the second HTL 252, and the third HTL 253 may have similar or identical structure and materials as the HTL 150 of FIG. 1. In one embodiment, the first ETL 271, the second ETL 272, and the third ETL 273 may have similar or identical structure and materials as the ETL 170 of FIG. 1.

Furthermore, an organic light-emitting diode according to an embodiment of the present disclosure may include a tandem structure in which four or more light-emitting stacks and three or more charge generating layers are disposed between the first electrode and the second electrode.

The organic light-emitting diode according to the present disclosure may be used as a light-emitting element of each of an organic light-emitting display device and a lighting device. In one implementation, FIG. 4 is a cross-sectional view schematically illustrating an organic light-emitting display device including the organic light-emitting diode according to some embodiments of the present disclosure as a light-emitting element thereof.

As shown in FIG. 4, an organic light-emitting display device 3000 includes a substrate 3010, an organic light-emitting diode 4000, and an encapsulation film 3900 covering the organic light-emitting diode 4000. A driving thin-film transistor Td as a driving element, and the organic light-emitting diode 4000 connected to the driving thin-film transistor Td are positioned on the substrate 3010.

Although not shown explicitly in FIG. 4, a gate line and a data line that intersect each other to define a pixel area, a power line extending parallel to and spaced from one of the gate line and the data line, a switching thin film transistor connected to the gate line and the data line, and a storage capacitor connected to one electrode of the thin film transistor and the power line are further formed on the substrate 3010.

The driving thin-film transistor Td is connected to the switching thin film transistor, and includes a semiconductor layer 3100, a gate electrode 3300, a source electrode 3520, and a drain electrode 3540.

The semiconductor layer 3100 may be formed on the substrate 3010 and may be made of an oxide semiconductor material or polycrystalline silicon. When the semiconductor layer 3100 is made of an oxide semiconductor material, a light-shielding pattern (not shown) may be formed under the semiconductor layer 3100. The light-shielding pattern prevents light from being incident into the semiconductor layer 3100 to prevent the semiconductor layer 3100 from being deteriorated due to the light. Alternatively, the semiconductor layer 3100 may be made of polycrystalline silicon. In this case, both edges of the semiconductor layer 3100 may be doped with impurities.

The gate insulating layer 3200 made of an insulating material is formed over an entirety of a surface of the substrate 3010 and on the semiconductor layer 3100. The gate insulating layer 3200 may be made of an inorganic insulating material such as silicon oxide or silicon nitride.

The gate electrode 3300 made of a conductive material such as a metal is formed on the gate insulating layer 3200 and corresponds to a center of the semiconductor layer 3100. The gate electrode 3300 is connected to the switching thin film transistor.

The interlayer insulating layer 3400 made of an insulating material is formed over the entirety of the surface of the substrate 3010 and on the gate electrode 3300. The interlayer insulating layer 3400 may be made of an inorganic insulating material such as silicon oxide or silicon nitride, or an organic insulating material such as benzocyclobutene or photo-acryl.

The interlayer insulating layer 3400 has first and second semiconductor layer contact holes 3420 and 3440 defined therein respectively exposing both opposing sides of the semiconductor layer 3100. The first and second semiconductor layer contact holes 3420 and 3440 are respectively positioned on both opposing sides of the gate electrode 3300 and are spaced apart from the gate electrode 3300.

The source electrode 3520 and the drain electrode 3540 made of a conductive material such as metal are formed on the interlayer insulating layer 3400. The source electrode 3520 and the drain electrode 3540 are positioned around the gate electrode 3300, and are spaced apart from each other, and respectively contact both opposing sides of the semiconductor layer 3100 via the first and second semiconductor layer contact holes 3420 and 3440, respectively. The source electrode 3520 is connected to a power line (not shown).

The semiconductor layer 3100, the gate electrode 3300, the source electrode 3520, and the drain electrode 3540 constitute the driving thin-film transistor Td. The driving thin-film transistor Td has a coplanar structure in which the gate electrode 3300, the source electrode 3520, and the drain electrode 3540 are positioned on top of the semiconductor layer 3100.

Alternatively, the driving thin-film transistor Td may have an inverted staggered structure in which the gate electrode is disposed under the semiconductor layer while the source electrode and the drain electrode are disposed above the semiconductor layer. In this case, the semiconductor layer may be made of amorphous silicon. In one example, the switching thin-film transistor (not shown) may have substantially the same structure as that of the driving thin-film transistor (Td).

In one example, the organic light-emitting display device 3000 may include a color filter 3600 absorbing the light generated from the electroluminescent element (light-emitting diode) 4000. For example, the color filter 3600 may absorb red (R), green (G), blue (B), and white (W) light. In this case, red, green, and blue color filter patterns that absorb light may be formed separately in different pixel areas. Each of these color filter patterns may be disposed to overlap each organic layer 4300 of the organic light-emitting diode 4000 to emit light of a wavelength band corresponding to each color filter. Adopting the color filter 3600 may allow the organic light-emitting display device 3000 to realize full-color.

For example, when the organic light-emitting display device 3000 is of a bottom emission type, the color filter 3600 absorbing light may be positioned on a portion of the interlayer insulating layer 3400 corresponding to the organic light-emitting diode 4000. In an optional embodiment, when the organic light-emitting display device 3000 is of a top emission type, the color filter may be positioned on top of the organic light-emitting diode 4000, that is, on top of a second electrode 4200. For example, the color filter 3600 may be formed to have a thickness of 2 to 5 µm.

In one example, a protective layer 3700 having a drain contact hole 3720 defined therein exposing the drain electrode 3540 of the driving thin-film transistor Td is formed to cover the driving thin-film transistor Td.

On the protective layer 3700, each first electrode 4100 connected to the drain electrode 3540 of the driving thin-film transistor Td via the drain contact hole 3720 is formed individually in each pixel area.

The first electrode 4100 may act as a positive electrode (anode), and may be made of a conductive material having a relatively large work function value. For example, the first electrode 4100 may be made of a transparent conductive material such as ITO, IZO or ZnO.

In one example, when the organic light-emitting display device 3000 is of a top-emission type, a reflective electrode or a reflective layer may be further formed under the first electrode 4100. For example, the reflective electrode or the reflective layer may be made of one of aluminum (Al), magnesium (Mg), silver (Ag), nickel (Ni), and an aluminum-palladium-copper (APC) alloy.

A bank layer 3800 covering an edge of the first electrode 4100 is formed on the protective layer 3700. The bank layer 3800 exposes a center of the first electrode 4100 corresponding to the pixel area.

An organic layer 4300 is formed on the first electrode 4100. If necessary, the organic light-emitting diode 4000 may have a tandem structure. Regarding the tandem structure, reference may be made to FIG. 2 to FIG. 4 which show some embodiments of the present disclosure, and the above descriptions thereof.

The second electrode 4200 is formed on the substrate 3010 on which the organic layer 4300 has been formed. The second electrode 4200 is disposed over the entirety of the surface of the display area and is made of a conductive material having a relatively small work function value and may be used as a negative electrode (a cathode). For example, the second electrode 4200 may be made of one of aluminum (Al), magnesium (Mg), and an aluminum-magnesium alloy (Al-Mg).

The first electrode 4100, the organic layer 4300, and the second electrode 4200 constitute the organic light-emitting diode 4000.

An encapsulation film 3900 is formed on the second electrode 4200 to prevent external moisture from penetrating into the organic light-emitting diode 4000. Although not shown explicitly in FIG. 4, the encapsulation film 3900 may have a triple-layer structure in which a first inorganic layer, an organic layer, and an inorganic layer are sequentially stacked. However, the present disclosure is not limited thereto.

Hereinafter, Preparation Example and Present Example of the present disclosure will be described. However, following Present Example is only one example of the present disclosure. The present disclosure is not limited thereto.

### Preparation Example of Ligand

### Preparation of Ligand A

### Step 1) Preparation of Ligand A-3

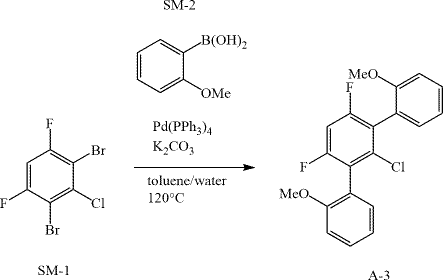

A compound SM-1 (6.12 g, 20 mmol), a compound SM-2 (3.04 g, 20 mmol), Pd(PPh₃)₄ (1.2 g, 1 mmol), and K₂CO₃ (8.3 g, 60 mmol) were dissolved in a mixture of 200 ml of toluene and 50 ml of water in a 500 ml round bottom flask under a nitrogen atmosphere, and a mixed solution was stirred under reflux for 12 hours. An organic layer was extracted therefrom with chloroform and washed with water. Moisture was removed therefrom with anhydrous magnesium sulfate, and a resulting product was filtered through a filter, and the organic solvent was distilled off under reduced pressure, followed by column purification to obtain the Compound A-3 (6.35 g, a yield: 88 %).

### Step 2) Preparation of Ligand A-2

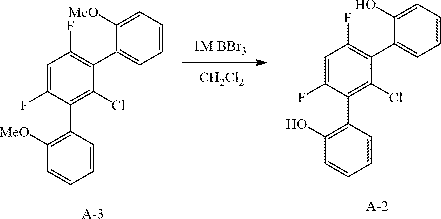

The Compound A-3 (7.22 g, 20 mmol), 1 M BBr₃ (46 ml, 46 mmol), and CH₂Cl₂ (300 ml) were added to a 500 ml round bottom flask under a nitrogen atmosphere, and a mixture was stirred at 0° C. for 8 hours, and reaction occurred overnight at room temperature. After completion of the reaction, a reaction product was neutralized with a saturated aqueous NaHCO₃ solution. A sample was transferred to a separatory funnel, and was subjected to extraction with CH₂Cl₂, and was purified using column chromatography to prepare the Compound A-2 (5.93 g, a yield: 89 %).

### Step 3) Preparation of Ligand A-1

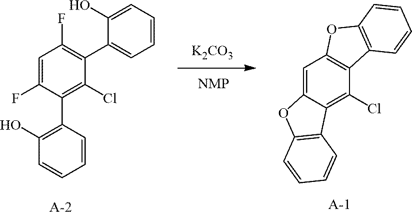

The Compound A-2 (6.66 g, 20 mmol), K₂CO₃ (6.07 g, 44 mmol), and NMP (200 ml) were input into a 500 ml round bottom flask under a nitrogen atmosphere, and a mixture was stirred at 150 degree C for 8 hours, and then cooled to room temperature. A sample was transferred to a separatory funnel, and water (200 ml) was added thereto, and was subjected to extraction with AcOEt. The sample was purified using column chromatography. Thus, the Compound A-1 (5.16 g, a yield: 88%) was prepared.

### Step 4) Preparation of Ligand A

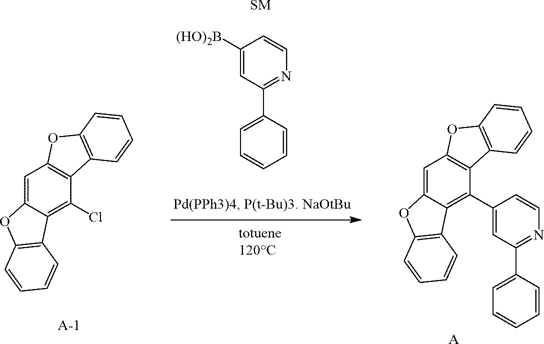

The Compound A-1 (5.86 g, 20 mmol), a compound SM (3.98 g, 20 mmol), Pd(PPh₃)₄ (2.3 g, 2 mmol), P(t-Bu)₃ (0.81 g, 4 mmol) and NaOtBu (7.7 g, 80 mmol) were dissolved in 200 ml of toluene in a 500 ml round bottom flask under a nitrogen atmosphere, and a mixed solution was stirred under reflux for 12 hours. An organic layer was extracted therefrom with chloroform and washed with water. Moisture was removed therefrom with anhydrous magnesium sulfate, and a resulting product was filtered through a filter, and the organic solvent was distilled off under reduced pressure, followed by column purification to obtain the Compound A (7.33 g, a yield: 89%).

### Preparation of Ligand B

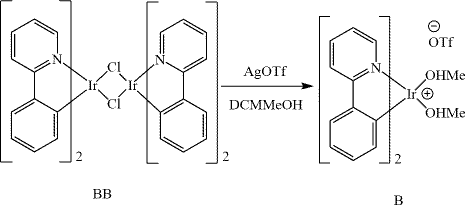

BB (5.16 g, 4.8 mmol), silver trifluoromethanesulfonate (AgOTf, 3.6 g, 14.3 mmol), and dichloromethane were placed into a 1000 ml round-bottom flask and a mixture was stirred at room temperature for 16 hours for reaction. After the reaction is completed, a solid is removed therefrom via filtration using celite. The solvent was distilled off under reduced pressure. Thus, the resulting solid Compound B (6.03 g, a yield: 88%) was obtained.

### Preparation of Ligand C

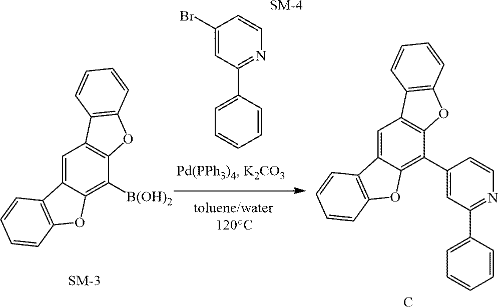

A compound SM-3 (6.04 g, 20 mmol), a compound SM-4 (4.68 g, 20 mmol), Pd(PPh₃)₄ (1.2 g, 1 mmol), and K₂CO₃ (8.3 g, 60 mmol) were dissolved in a mixture of 200 ml of toluene and 50 ml of water and a mixed solution was stirred under reflux for 12 hours. An organic layer was extracted therefrom with chloroform and washed with water. Moisture was removed therefrom with anhydrous magnesium sulfate, and a resulting product was filtered through a filter, and the organic solvent was distilled off under reduced pressure, followed by column purification to obtain the Compound C (7.48 g, a yield: 91%).

### <Preparation Example of Organometallic Compound>

### Preparation of Compound 1

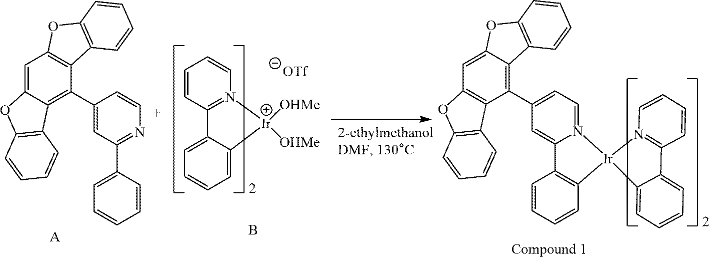

The iridium precursor B (2.15 g. 3.5 mmol) and the ligand A (1.44 g, 3 mmol) were dissolved in a mixed solvent (2-ethoxyethanol: DMF = 40 ml: 40 ml) in a 100 ml round bottom flask under a nitrogen atmosphere and a mixed solution was stirred at 130 degrees C for 48 hours for reaction. After the reaction was completed, an organic layer was extracted therefrom with dichloromethane and distilled water, and the solvent was removed therefrom via distillation under reduced pressure. A crude product was subjected to column chromatography with toluene: hexane to obtain the Compound 1 (2.57 g, a yield: 94%).

### Preparation of Compound 13

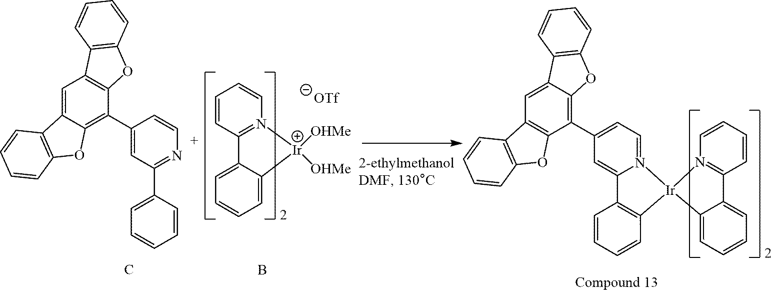

The iridium precursor B (2.15 g. 3.5 mmol) and the ligand C (1.44 g, 3 mmol) were dissolved in a mixed solvent (2-ethoxyethanol: DMF = 40 ml: 40 ml) in a 100 ml round bottom flask under a nitrogen atmosphere, and a mixed solution was stirred at 130 degrees C for 48 hours for reaction. After the reaction was completed, an organic layer was extracted therefrom with dichloromethane and distilled water, and the solvent was removed via distillation under reduced pressure. A crude product was subjected to column chromatography with toluene: hexane to obtain the Compound 13 (2.48 g, a yield: 83%).

### <Present Example>

### 1. Fabrication of Organic Light-emitting Diode

A glass substrate having a thin film of ITO (indium tin oxide) having a thickness of 1,000 Å coated thereon was washed, followed by ultrasonic cleaning with a solvent such as isopropyl alcohol, acetone, and methanol. Then, the glass substrate was dried. Thus, an ITO transparent electrode was formed. HATCN as a hole injection material was deposited on the ITO transparent electrode in a thermal vacuum deposition manner. Thus, a hole injection layer having a thickness of 10 nm was formed. Then, NPB as a hole transfer material was deposited on the hole injection layer in a thermal vacuum deposition manner. Thus, a hole transfer layer having a thickness of 30 nm was formed.

Then, DMAC-BPP as a host material of a red light-emitting layer was deposited on the hole transfer layer in a thermal vacuum deposition manner. Ir(piq)₂(acac) as the dopant was doped into the host material at a doping concentration of 5%. The Compound 1 as the charge scavenger was doped into the host material at a doping concentration of 3%. Thus, the red light-emitting layer of a thickness of 20 nm was formed.

ZADN (thickness: 25 nm) as an electron transfer material was deposited on the red light-emitting layer in a thermal vacuum deposition manner. Then, BPhen+Li (thickness: 20 nm) as an electron injection material was deposited on the electron transfer layer in a thermal vacuum deposition manner. Then, 100 nm thick aluminum was deposited thereon to form a negative electrode. In this way, an organic light-emitting diode was manufactured.

### 2. Performance Test of Organic Light-emitting Diode

Data on the manufactured organic light-emitting diode were recorded and calculated as follows.

1) Each of CIEx and CIEy was recorded according to the CIE 1931 chromaticity coordinate system.

2) External quantum efficiency (EQE, %) was measured at a current density of 10 mA/cm² using a luminance meter.

3) EQE at a current density in a range of from 0.25 mA/cm² to 100 mA/cm² was measured. Then, a normalized EQE at each current density based on EQE at 0.25 mA/cm² was calculated.

4) A roll-off value was calculated according to a following Equation 1 based on the normalized EQE values at 0.25 mA/cm² and 100 mA/cm², respectively:

$$R o l l - o f f \left(\%\right) = \frac{N o r m a l i z e d E Q E @ 1.00 \text{mA} / \text{cm2}}{N o r m a l i z e d E Q E @ 0.25 \text{mA} / \text{cm2}} \times 100$$

The meaning of Equation 1 refers to a percentage of a ratio of the EQE at a high gray level (100 mA/cm²) to the EQE at a low gray level (0.25 mA/cm²). The roll-off value was set as a rate at which EQE decreases as the current density value increases.

Further, when the roll-off value (%) in each experimental group is larger compared to a reference value, this means that the roll-off phenomenon is reduced.

### <Experimental Group 1>: Comparative Examples 1-1 to 1-3 and Present Examples 1-1 to 1-2

An organic light-emitting diode was fabricated in the same manner as in section 1 of the <Present Example> as described above except that a material of the charge scavenger and a material of HTL were used as shown in a following Table 1. That is, Comparative Example 1-1 did not include the charge scavenger. Comparative Examples 1-2 and 1-3 employed Ir(ppy)₂(acac) and FIrPic instead of the Compound 1 as the charge scavenger, respectively. Present Examples 1-1 and 1-2 employed the Compounds 1 and 13 as the charge scavenger, respectively. (That is, the <Present Example > as described above corresponds to Present Example 1-1 of Experimental Group 1.)

The performance test of the organic light-emitting diode of each of the organic light-emitting diodes of Comparative Examples 1-1 to 1-3 and Present Examples 1-1 to 1-2 was performed in the same manner as in section 2 of the <Present Example> as descried above. The test result is described in Table 2. In Experimental Group 1, test result values of Comparative Example 1-1 were set as reference values.

TABLE 1

| | | | | |
|---|---|---|---|---|
| Examples | Host | Dopant | Charge scavenger | HTL |
| Comparative Example 1-1 | DMAC-BPP | Ir(piq)₂(acac) | - | TAPC |
| Comparative Example 1-2 | DMAC-BPP | Ir(piq)₂(acac) | Ir(ppy)₂(acac) | TAPC |
| Comparative Example 1-3 | DMAC-BPP | Ir(piq)₂(acac) | FIrPic | TAPC |
| Present Example 1-1 | DMAC-BPP | Ir(piq)₂(acac) | Compound 1 | TAPC |
| Present Example 1-2 | DMAC-BPP | Ir(piq)₂(acac) | Compound 13 | TAPC |

A HOMO energy level of Ir(piq)₂(acac) is in a range of -5.0(eV) to -5.1(eV), and T₁ thereof is 2.00(eV).

A HOMO energy level of Ir(ppy)₂(acac) is -4.95(eV), and T₁ thereof is 2.47(eV).

A HOMO energy level of FIrPic is -5.6 (eV), and T₁ thereof is 2.65 (eV).

A HOMO energy level of the Compound 1 is -5.12 (eV), and T₁ thereof is 2.25 (eV).

A HOMO energy level of the Compound 13 is -5.12 (eV), and T₁ thereof is 1.95 (eV).

A HOMO energy level of TAPC is -5.5 (eV).

TABLE 2

| Examples | EQE | Normalized EQE (@ 0.25 mA/cm²) | Normalized EQE (@ 100 mA/cm²) | Roll-off | CIEx | CIEy |
|---|---|---|---|---|---|---|
| Comparative Example 1-1 | 100% | 1.0 | 0.53 | 53 % | 0.680 | 0.317 |
| Comparative Example 1-2 | 96% | 1.0 | 0.53 | 52% | 0.679 | 0.318 |
| Comparative Example 1-3 | 94% | 1.0 | 0.52 | 52% | 0.679 | 0.319 |
| Present Example 1-1 | 110% | 1.0 | 0.57 | 57 % | 0.680 | 0.317 |
| Present Example 1-2 | 102% | 1.0 | 0.54 | 54% | 0.676 | 0.322 |

It is identified from the results of the Tables 1 and 2 that when each of Present Examples 1-1 and 1-2 in which the light-emitting layer is doped with the charge scavenger that satisfies the condition (1) or both the conditions (1) and (2) of the present disclosure is compared with Comparative Example 1-1, a red light-emitting layer of each of Present Examples 1-1 and 1-2 is realized such that EQE (%) of each of Present Examples 1-1 and 1-2 increases, and the roll-off value thereof is increased. On the contrary, each of Comparative Examples 1-2 and 1-3 in which the light-emitting layer is doped with the charge scavenger that does not satisfy the conditions (1) and (2) has EQE (%) lower than that of Comparative Example 1-1 in which the light-emitting layer is not doped with the charge scavenger, and has a roll-off value smaller than that of Comparative Example 1-1, resulting in deteriorated results.

### <Experimental Group 2> : Comparative Examples 2-1 to 2-3 and Present Examples 2-1 to 2-2

An organic light-emitting diode was fabricated in the same manner as in 1. of the <Present Example> as described above except that a material of the dopant, a material of the charge scavenger and a material of HTL were used as shown in a following Table 3.

That is, in Comparative Examples 2-1 to 2-3 and Present Examples 2-1 to 2-2, the material of the dopant was not Ir(piq)₂(acac) but Ir(2-phq)₃. Comparative Example 2-1 did not include the charge scavenger. Comparative Examples 2-2 and 2-3 employed Ir(ppy)₂(acac) and FIrPic instead of the Compound 1 as the charge scavenger, respectively. Present Examples 2-1 and 2-2 employed the Compounds 1 and 13 as the charge scavenger, respectively.

The performance test of the organic light-emitting diode of each of the organic light-emitting diodes of Comparative Examples 2-1 to 2-3 and Present Examples 2-1 to 2-2 was performed in the same manner as in 2. of the <Present Example> as descried above. The test result is described in Table 4. In Experimental Group 2, test result values of Comparative Example 2-1 were set as reference values.

TABLE 3

| | | | | |
|---|---|---|---|---|
| Examples | Host | Dopant | Charge scavenger | HTL |
| Comparative Example 2-1 | DMAC-BPP | Ir(2-phq)₃ | - | TAPC |
| Comparative Example 2-2 | DMAC-BPP | Ir(2-phq)₃ | Ir(ppy)₂(acac) | TAPC |
| Comparative Example 2-3 | DMAC-BPP | Ir(2-phq)₃ | FIrPic | TAPC |
| Present Example 2-1 | DMAC-BPP | Ir(2-phq)₃ | Compound 1 | TAPC |
| Present Example 2-2 | DMAC-BPP | Ir(2-phq)₃ | Compound 13 | TAPC |

A HOMO energy level of Ir(2-phq)₃ is 5.1 (eV), and T₁ thereof is 2.00 (eV).

The energy levels of Ir(ppy)₂(acac), FIrPic, Compound 1, Compound 13 and TAPC were the same as described above.

TABLE 4

| Examples | EQE | Normalized EQE (@ 0.25 mA/cm²) | Normalized EQE (@ 100 mA/cm²) | Roll-off | CIEx | CIEy |
|---|---|---|---|---|---|---|
| Comparative Example 2-1 | 100% | 1.0 | 0.54 | 54 % | 0.670 | 0.328 |
| Comparative Example 2-2 | 96% | 1.0 | 0.52 | 52 % | 0.670 | 0.328 |
| Comparative | 93% | 1.0 | 0.51 | 51 % | 0.666 | 0.333 |
| Present Example 2-1 | 111% | 1.0 | 0.57 | 57 % | 0.670 | 0.328 |
| Present Example 2-2 | 103% | 1.0 | 0.53 | 53 % | 0.666 | 0.333 |

It is identified from the results of the Tables 3 and 4 that when each of Present Examples 2-1 and 2-2 in which the light-emitting layer is doped with the charge scavenger that satisfies the condition (1) or both the conditions (1) and (2) of the present disclosure is compared with Comparative Example 2-1, a red light-emitting layer of each of Present Examples 2-1 and 2-2 is realized such that EQE (%) of each of Present Examples 2-1 and 2-2 increases, and the roll-off value thereof is increased. On the contrary, each of Comparative Examples 2-2 and 2-3 in which the light-emitting layer is doped with the charge scavenger that does not satisfy the conditions (1) and (2) has EQE (%) lower than that of Comparative Example 2-1 in which the light-emitting layer is not doped with the charge scavenger, and has a roll-off value smaller than that of Comparative Example 2-1, resulting in deteriorated results.

### <Experimental Group 3> : Reference Comparative Example 1 and Reference Experimental Examples 1 to 10

An organic light-emitting diode was fabricated in the same manner as in 1. of the <Present Example> as described above except that a material of the dopant, a material of the charge scavenger and a material of HTL were used as shown in a following Table 5. That is, Reference Comparative Example 1 was free of the charge scavenger. Organic light-emitting diodes were fabricated while increasing the doping concentration of the Compound 1 doped as the charge scavenger from 1% to 10% by 1% (Reference Experimental Examples 1 to 10).

The performance test of the organic light-emitting diode of each of the organic light-emitting diodes of Reference Comparative Example 1 and Reference Experimental Examples 1 to 9 was performed in the same manner as in section 2 of the <Present Example> as described above. The test result is described in Table 6. In Experimental Group 3, test result values of Reference Comparative Example 1 were set as reference values.

TABLE 5

| | | | | |
|---|---|---|---|---|
| Examples | Host | Dopant (5%) | Charge scavenger (doping concentration) | HTL |
| Reference Comparative Example 1 | DMAC-BPP | Ir(piq)₂(acac) | - | TAPC |
| Reference Experimental Example 1 | DMAC-BPP | Ir(piq)₂(acac) | Compound 1 (1 %) | TAPC |
| Reference Experimental Example 2 | DMAC-BPP | Ir(piq)₂(acac) | Compound 1 (2%) | TAPC |
| Reference Experimental Example 3 | DMAC-BPP | Ir(piq)₂(acac) | Compound 1 (3%) | TAPC |
| Reference Experimental Example 4 | DMAC-BPP | Ir(piq)₂(acac) | Compound 1 (4%) | TAPC |
| Reference Experimental Example 5 | DMAC-BPP | Ir(piq)₂(acac) | Compound 1 (5%) | TAPC |
| Reference Experimental Example 6 | DMAC-BPP | Ir(piq)₂(acac) | Compound 1 (6%) | TAPC |
| Reference Experimental Example 7 | DMAC-BPP | Ir(piq)₂(acac) | Compound 1 (7%) | TAPC |
| Reference Experimental Example 8 | DMAC-BPP | Ir(piq)₂(acac) | Compound 1 (8%) | TAPC |
| Reference Experimental Example 9 | DMAC-BPP | Ir(piq)₂(acac) | Compound 1 (9%) | TAPC |
| Reference Experimental Example 10 | DMAC-BPP | Ir(piq)₂(acac) | Compound 1 (10%) | TAPC |

TABLE 6

| Examples | EQE | Normalized EQE (@ 0.25 mA/cm²) | Normalized EQE (@ 100 mA/cm²) | Roll-off | CIEx | CIEy |
|---|---|---|---|---|---|---|
| Reference Comparative Example 1 | 100% | 1.0 | 0.53 | 53 % | 0.680 | 0.317 |
| Reference Experimental Example 1 | 107% | 1.0 | 0.57 | 57 % | 0.680 | 0.317 |
| Reference Experimental Example 2 | 107% | 1.0 | 0.57 | 57 % | 0.680 | 0.317 |
| Reference Experimental Example 3 | 110% | 1.0 | 0.57 | 57 % | 0.680 | 0.317 |
| Reference Experimental Example 4 | 112% | 1.0 | 0.57 | 57 % | 0.680 | 0.317 |
| Reference Experimental Example 5 | 113% | 1.0 | 0.57 | 57 % | 0.680 | 0.317 |
| Reference Experimental Example 6 | 114% | 1.0 | 0.58 | 58 % | 0.680 | 0.317 |
| Reference Experimental Example 7 | 114% | 1.0 | 0.58 | 58 % | 0.680 | 0.317 |
| Reference Experimental Example 8 | 115% | 1.0 | 0.58 | 58 % | 0.680 | 0.318 |
| Reference Experimental Example 9 | 113% | 1.0 | 0.57 | 57 % | 0.678 | 0.320 |
| Reference Experimental Example 10 | 112% | 1.0 | 0.56 | 56 % | 0.676 | 0.322 |

As can be identified from the results of the Tables 5 and 6, when the Compound 1 satisfying the conditions (1) and (2) of the present disclosure is used as the charge scavenger doped into the red light-emitting layer, and even when the doping concentration thereof is only 1%, Reference Experimental Example 1 has EQE (%) and the roll-off value larger than those in reference Comparative Example 1 in which the charge scavenger is not doped into the red light-emitting layer.

However, Reference Experimental Example 10 in which the doping concentration (10%) of the charge scavenger is twice the doping concentration (5%) of the dopant has a difference of 0.004 in CIEx and a difference of 0.005 in CIEy from those in Reference Comparative Example 1, respectively. Thus, in fact, it was observed that a color of light from the organic light-emitting diode of Reference Experimental Example 10 was greenish. Thus, it was identified that when the doping concentration of the charge scavenger was larger than or equal to two times of the doping concentration of the dopant, an exact target red color was not rendered.

A scope of protection of the present disclosure should be construed by the scope of the claims, and all technical ideas within the scope equivalent thereto should be construed as being included in the scope of the present disclosure. Although the embodiments of the present disclosure have been described in more detail with reference to the accompanying drawings, the present disclosure is not necessarily limited to these embodiments. The present disclosure may be implemented in various modified manners within the scope not departing from the technical idea of the present disclosure. Accordingly, the embodiments disclosed in the present disclosure are not intended to limit the technical idea of the present disclosure, but to describe the present disclosure. the scope of the technical idea of the present disclosure is not limited by the embodiments. Therefore, it should be understood that the embodiments as described above are illustrative and non-limiting in all respects. The scope of protection of the present disclosure should be interpreted by the claims, and all technical ideas within the scope of the present disclosure should be interpreted as being included in the scope of the present disclosure.

What is claimed is:

1. An organometallic compound represented by a following Chemical Formula 1: 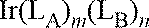
wherein in the Chemical Formula 1,
L_{A} is a main ligand represented by one selected from a group consisting of following Chemical Formula 2-1 to Chemical Formula 2-3,
L_{B} is an ancillary ligand represented by a following Chemical Formula 3: 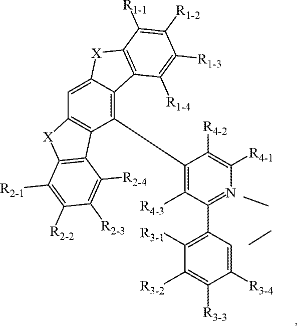 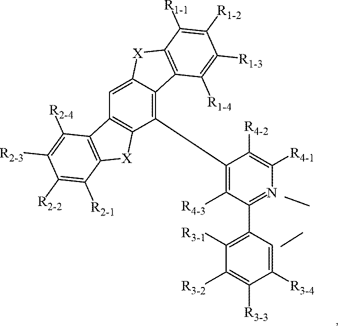 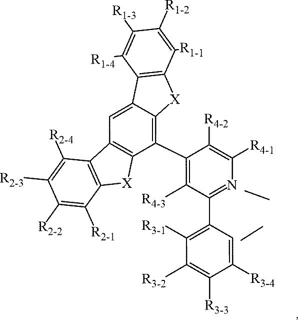 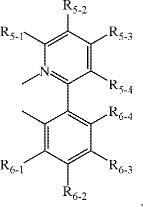
wherein in each of the Chemical Formulas 2-1 to 2-3,
X represents one selected from a group consisting of O, S, NR₇, and C(R₈)(R₉),
each of R₁₋₁, R₁₋₂, R₁₋₃, R₁₋₄, R₂₋₁, R₂₋₂, R₂₋₃, R₂₋₄, R₃₋₁, R₃₋₂, R₃₋₃, R₃₋₄, R₄₋₁, R₄₋₂ and R₄₋₃ independently represents one selected from a group consisting of hydrogen, deuterium, halide, C1-C30 alkyl, C3-C30 cycloalkyl, C1-C30 heteroalkyl, C1-C30 arylalkyl, C1-C30 alkoxy, C1-C30 aryloxy, amino, silyl, C2-C30 alkenyl, C3-C30 cycloalkenyl, C3-C30 heteroalkenyl, C2-C30 alkynyl, C6-C40 aryl, C3-C40 heteroaryl, acyl, carbonyl, carboxylic acid, ester, nitrile, isonitrile, sulfanyl, sulfinyl, sulfonyl, phosphino, and combinations thereof,
two adjacent substituents among R₁₋₁, R₁₋₂, R₁₋₃, R₁₋₄, R₂₋₁, R₂₋₂, R₂₋₃, R₂₋₄, R₃₋₁, R₃₋₂, R₃₋₃, R₃₋₄, R₄₋₁, R₄₋₂ and R₄₋₃ are connected to each other to form one ring structure selected from a group consisting of a substituted or unsubstituted C3-C20 cycloalkyl group, a substituted or unsubstituted C2-C20 heterocycloalkyl group, a substituted or unsubstituted C7-C20 arylalkyl group, a substituted or unsubstituted C2-C20 heteroarylalkyl group, a substituted or unsubstituted C3-C20 cycloalkenyl group, a substituted or unsubstituted C6-C30 aryl group, and a substituted or unsubstituted C3-C30 heteroaryl group,
each of R₇, R₈, and R₉ independently represents one selected from a group consisting of C1-C30 alkyl, C3-C30 cycloalkyl, C1-C30 heteroalkyl, C1-C30 arylalkyl, C1-C30 alkoxy, C1-C30 aryloxy, amino, silyl, C2-C30 alkenyl, C3-C30 cycloalkenyl, C3-C30 heteroalkenyl, C2-C30 alkynyl, C6-C40 aryl, and C3-C40 heteroaryl,
wherein in the Chemical Formula 3,
each of R₅₋₁, R₅₋₂, R₅₋₃, R₅₋₄, R₆₋₁, R₆₋₂, R₆₋₃ and R₆₋₄ independently represents one selected from a group consisting of hydrogen, deuterium, a C1-C5 straight-chain alkyl group, and a C1-C5 branched alkyl group, wherein the C1-C5 straight-chain alkyl group or C1-C5 branched alkyl group may be substituted with at least one selected from deuterium and halogen,
two adjacent substituents among R₅₋₁, R₅₋₂, R₅₋₃, R₅₋₄, R₆₋₁, R₆₋₂, R₆₋₃ and R₆₋₄ are connected to each other to form one ring structure selected from a group consisting of a substituted or unsubstituted C3-C20 cycloalkyl group, a substituted or unsubstituted C2-C20 heterocycloalkyl group, a substituted or unsubstituted C7-C20 arylalkyl group, a substituted or unsubstituted C2-C20 heteroarylalkyl group, a substituted or unsubstituted C3-C20 cycloalkenyl group, a substituted or unsubstituted C6-C30 aryl group, and a substituted or unsubstituted C3-C30 heteroaryl group, and
m is 1, 2 or 3, n is 0, 1 or 2, and a sum of m and n is 3.

2. The organometallic compound of claim 1, wherein m is 1 and n is 2.

3. The organometallic compound of claim 1, wherein m is 2 and n is 1.

4. The organometallic compound of claim 1, wherein m is 3 and n is 0.

5. The organometallic compound of claim 1, wherein the compound represented by the Chemical Formula 1 includes one selected from a group consisting of following compounds 1 to 20:

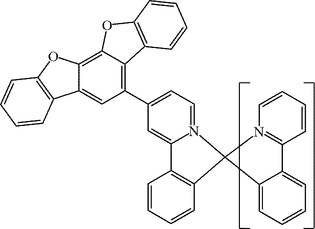

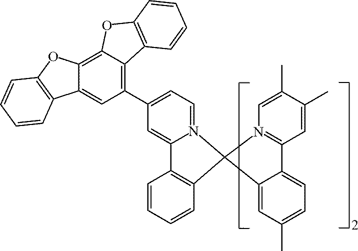

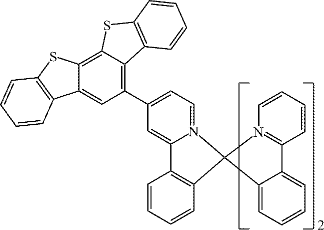

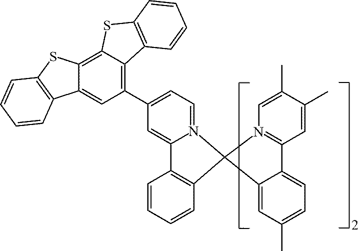

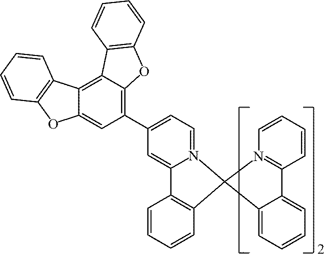

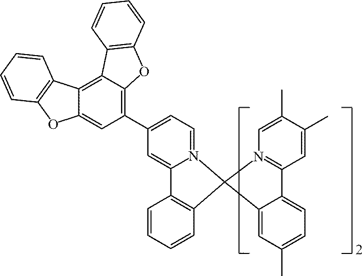

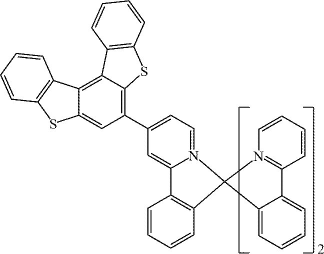

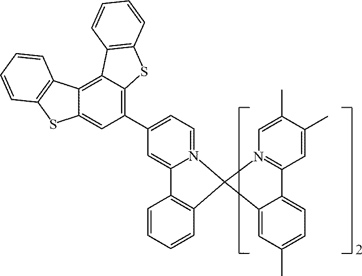

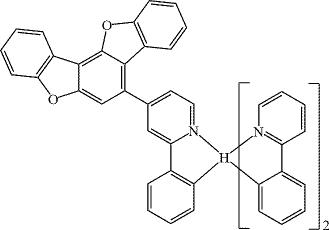

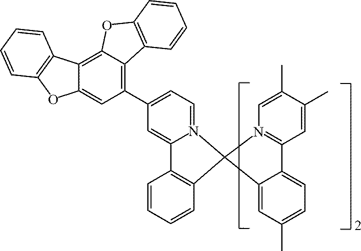

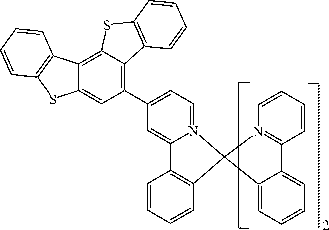

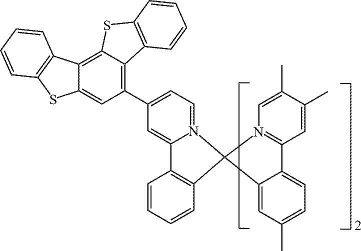

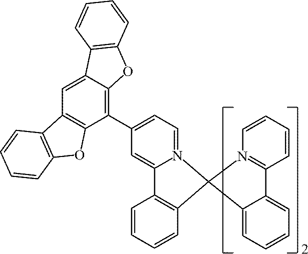

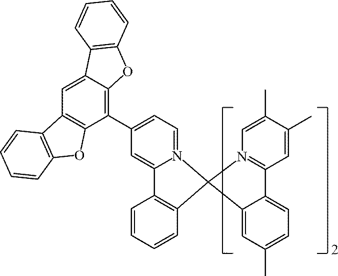

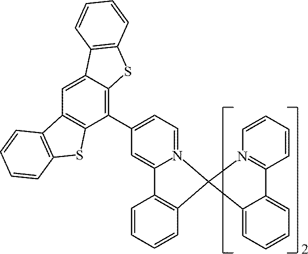

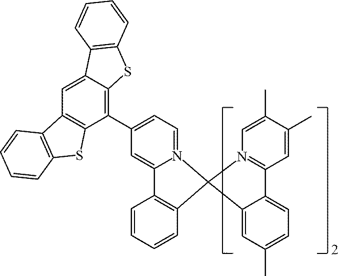

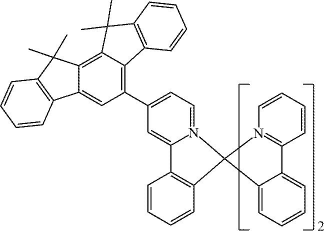

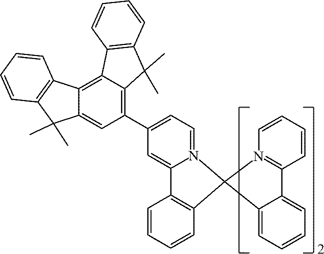

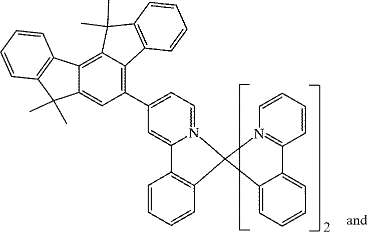

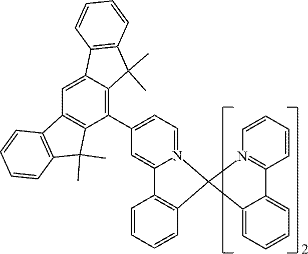

6. An organic light-emitting device comprising:
a first electrode;
a second electrode facing the first electrode; and
a light-emitting stack disposed between the first electrode and the second electrode,
wherein the light-emitting stack includes an organic layer,
wherein the organic layer includes a hole transfer layer and a red light-emitting layer,
wherein the hole transfer layer includes a hole transfer material,
wherein the red light-emitting layer includes a red host, a red dopant, and a charge scavenger,
wherein the charge scavenger includes the organometallic compound of claim 1.

7. The organic light-emitting device of claim 6, wherein the device satisfies a following condition (1): 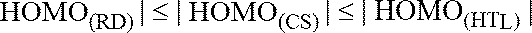
wherein in the condition (1), | HOMO_{(RD)} | denotes an absolute value of a HOMO energy level of the red dopant, and | HOMO_{(CS)} | denotes an absolute value of a HOMO energy level of the charge scavenger, and | HOMO_{(HTL)} | denotes an absolute value of a HOMO energy level of the hole transfer material.

8. The organic light-emitting device of claim 6, wherein the organic light-emitting device further satisfies a following condition (2): 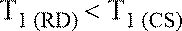
wherein in the condition (2), T₁_{(RD)} denotes a triplet energy level of the red dopant, and T₁_{(CS)} denotes a triplet energy level of the charge scavenger.

9. The organic light-emitting device of claim 8, wherein T₁_{(RD)} is in a range of 1.8 to 2.2 eV,
wherein T₁_{(CS)} is lower than or equal to 2.6 eV.

10. The organic light-emitting device of claim 6, wherein a doping concentration of the red dopant is in a range of 1 to 30% by weight based on a total weight of the red host,
wherein a doping concentration of the charge scavenger is in a range of 1 to 30% by weight by weight based on a total weight of the red host.

11. The organic light-emitting device of claim 10, wherein the doping concentration of the charge scavenger is smaller than two times of the doping concentration of the red dopant.

12. The organic light-emitting device of claim 6, wherein the organic layer further includes at least one of a hole injection layer, an electron transfer layer, or an electron injection layer.

13. An organic light-emitting device comprising:
a first electrode;
a second electrode facing the first electrode; and
a first light-emitting stack and a second light-emitting stack positioned between the first electrode and the second electrode,
wherein each of the first light-emitting stack and the second light-emitting stack includes at least one light-emitting layer,
wherein the at least one light-emitting layer of at least one of the first light-emitting stack or the second light-emitting stack includes a red light-emitting layer,
wherein the red light-emitting layer includes a red host, a red dopant, and a charge scavenger,
wherein the charge scavenger includes the organometallic compound of claim 1.

14. An organic light-emitting device comprising:
a first electrode;
a second electrode facing the first electrode; and
a first light-emitting stack, a second light-emitting stack, and a third light-emitting stack positioned between the first electrode and the second electrode,
wherein each of the first light-emitting stack, the second light-emitting stack, and the third light-emitting stack includes at least one light-emitting layer,
wherein the at least one light-emitting layer of at least one of the first light-emitting stack, the second light-emitting stack, or the third light-emitting stack includes a red light-emitting layer,
wherein the red light-emitting layer includes a red host, a red dopant, and a charge scavenger,
wherein the charge scavenger includes the organometallic compound of claim 1.

15. An organic light-emitting display device comprising:
a substrate;
a driving element positioned on the substrate; and
an organic light-emitting element disposed on the substrate and connected to the driving element, wherein the organic light-emitting element includes the organic light-emitting device according to claim 6.
